(19) United States
(12) Patent Application Publication
(10) Pub. No.: US 2021/0296392 A1
(43) Pub. Date: Sep. 23, 2021

(54) Flat Panel Array with the Alignment Marks in Active Area

(71) Applicant: dpiX, LLC, Colorado Springs, CO (US)

(72) Inventors: Ick-Hwan Ko, Colorado Springs, CO (US); Karthik Nagarajan, Colorado Springs, CO (US); Byung-Kyu Park, Colorado Springs, CO (US); Shawn Michael O'Rourke, Colorado Springs, CO (US)

(21) Appl. No.: 17/339,736

(22) Filed: Jun. 4, 2021

Related U.S. Application Data
(62) Division of application No. 15/423,355, filed on Feb. 2, 2017.
(60) Provisional application No. 62/418,003, filed on Nov. 4, 2016.

(51) Int. Cl. H01L 27/146; H01L 23/544; G03F 7/20; H01L 21/66

(52) U.S. Cl. CPC H01L 27/14685; H01L 23/544; H01L 27/14603; G03F 7/70633; H01L 22/12; H01L 22/20; H01L 2223/54426; H01L 2223/5442; H01L 22/30

(57) ABSTRACT

Test structures and alignment marks enable accurate measurements of alignment in the active area of an image sensor device. The alignment marks are formed in the active area replacing pixels near the lithographic shot boundaries of the array. Misalignment across the lithographic shots is assessed through the degree of shifting between the alignment patterns. The alignment marks are located in a pixel location of the active area and can measure the actual lithographic shot-to-shot misalignment in the active area, which can be used to make an accurate lithographic alignment. Having such alignment marks allows for a more accurate assessment of the in-line process manufacturing capability as well as a more rapid feedback of in-array drift, which would allow a faster and better control for yield loss.

### CROSS-REFERENCE TO RELATED APPLICATIONS

This application is a divisional of U.S. patent application Ser. No. 15/423,355, filed on Feb. 2, 2017, and entitled “FLAT PANEL ARRAY WITH THE ALIGNMENT MARKS IN ACTIVE AREA” which claims priority to U.S. Provisional Patent Application No. 62/418,003, filed on Nov. 4, 2016, which applications are hereby incorporated by reference in their entirety.

### TECHNICAL FIELD

This invention relates to a manufacturing method for a flat panel array or an image sensor device. More particularly, this invention relates to a manufacturing method of having an alignment mark in a pixel location in the active area to improve the lithographic shot-to-shot misalignment.

### BACKGROUND

Alignment marks are well known in the semiconductor industry for aligning the application of features on successive films used during the manufacturing process of, for example, an integrated circuit. While the use of alignment marks in general is well known, the type and location of the alignment marks may not be well suited for the precise alignment required in, for example, an image sensor device. What is desired, therefore, is a set of alignment marks and method of use that is well suited to a flat panel array or image sensor device such that all of the features in successive method steps are precisely aligned and cluster defects between adjacent pixels in the array is minimized.

### SUMMARY

An object according to the present invention is to provide novel test structures and alignment marks that enable accurate measurements of alignment in the active area of an image sensor device. The alignment marks are formed in the active area replacing pixels near the lithographic shot boundaries of the array. Misalignment across the lithographic shots is assessed through the degree of shifting between the alignment patterns. These alignment marks are located in a pixel location of the active area and can measure the actual lithographic shot-to-shot misalignment in the active area, which can be used to make an accurate lithographic alignment. Having such alignment marks allows for a more accurate assessment of the in-line process manufacturing capability as well as a more rapid feedback of in-array drift, which would allow a faster and better control for yield loss.

A first embodiment of the invention comprises an image sensor device comprising a glass substrate; an active area over the glass substrate; and a plurality of alignment marks within the active area, the alignment marks each comprising a plurality of square and rectangular features. At least one of the plurality of alignment marks is placed in a pixel location of the active area. At least one of the plurality of alignment marks is placed proximate to a lithographic boundary of the active area. At least one of the plurality of alignment marks comprises a plurality of layers. Additional alignment marks outside of the active area can also be used.

A second embodiment of the invention comprises an image sensor device comprising a glass substrate; an active area over the glass substrate; and a plurality of alignment marks within the active area, the alignment marks each comprising a plurality of overlapping rectangular features. At least one of the plurality of alignment marks is placed in a pixel location of the active area. At least one of the plurality of alignment marks is placed proximate to a lithographic boundary of the active area. At least one of the plurality of alignment marks comprises a plurality of layers. Additional alignment marks outside of the active area can also be used.

A third embodiment of the invention comprises a method of manufacturing an image sensor device comprising a glass substrate; forming at least one layer of the image sensor device, the at least one layer including a first plurality of alignment marks within an active area of the image sensor device, the alignment marks each comprising a plurality of square and rectangular features; coating the at least one layer with a film; coating the film with a photoresist layer, the photoresist layer including a second plurality of alignment marks within an active area of the image sensor device, the alignment marks each comprising a plurality of square and rectangular features; and inspecting the alignment between the first plurality of alignment marks and the second plurality of alignment marks. If the alignment between the first plurality of alignment marks and the second plurality of alignment marks is unacceptable, the photo resist layer is stripped. If the alignment between the first plurality of alignment marks and the second plurality of alignment marks is acceptable, the film is etched using the photoresist layer. At least one of the first or second plurality of alignment marks is placed in a pixel location of the active area. At least one of the plurality of alignment marks is placed proximate to a lithographic boundary of the active area. Additional alignment marks outside of the active area can also be used

A fourth embodiment of the invention comprises a method of manufacturing an image sensor device comprising a glass substrate; forming at least one layer of the image sensor device, the at least one layer including a first plurality of alignment marks within an active area of the image sensor device, the alignment marks each comprising a plurality of overlapping rectangular features; coating the at least one layer with a film; coating the film with a photoresist layer, the photoresist layer including a second plurality of alignment marks within an active area of the image sensor device, the alignment marks each comprising a plurality of overlapping rectangular features; and inspecting the alignment between the first plurality of alignment marks and the second plurality of alignment marks. If the alignment between the first plurality of alignment marks and the second plurality of alignment marks is unacceptable, the photoresist layer is stripped. If the alignment between the first plurality of alignment marks and the second plurality of alignment marks is acceptable, the film is etched using the photoresist layer. At least one of the first or second plurality of alignment marks is placed in a pixel location of the active area. At least one of the plurality of alignment marks is placed proximate to a lithographic boundary of the active area. Additional alignment marks outside of the active area can also be used.

### BRIEF DESCRIPTION OF THE DRAWINGS

FIG. 1A illustrates an image sensor array with alignment marks outside of the active area of the array;

FIG. 1B illustrates the misalignment between a first layer and a second layer using the alignment marks of FIG. 1A;

FIG. 1C illustrates the stitching errors that may occur at a lithographic shot boundary using the alignment marks of FIG. 1A;

FIG. 2A illustrates an image sensor array with alignment marks inside of the active area of the array according to the present invention;

FIG. 2B illustrates an image sensor array with alignment marks inside of and outside of the active area of the array according to the present invention;

FIGS. 3A-3I show a first embodiment of alignment marks that are placed in a pixel location of an active area of an image sensor device according to the present invention;

FIGS. 4A-4C show a portion of an image sensor array including alignment marks in various pixel locations according to the present invention;

FIGS. 5A-5C are a simplified version of the image sensor array corresponding to the sensor array shown in FIGS. 4A-4C according to the present invention;

FIGS. 6A and 6B show a second embodiment of the alignment marks of the present invention;

FIGS. 7A and 7B show flow charts for using alignment marks according to the present invention; and

FIGS. 8A-8E show manufacturing process steps wherein the alignment marks are lined up properly, and manufacturing process steps wherein the alignment marks are misaligned, according to the present invention.

### DETAILED DESCRIPTION OF ILLUSTRATIVE EMBODIMENTS

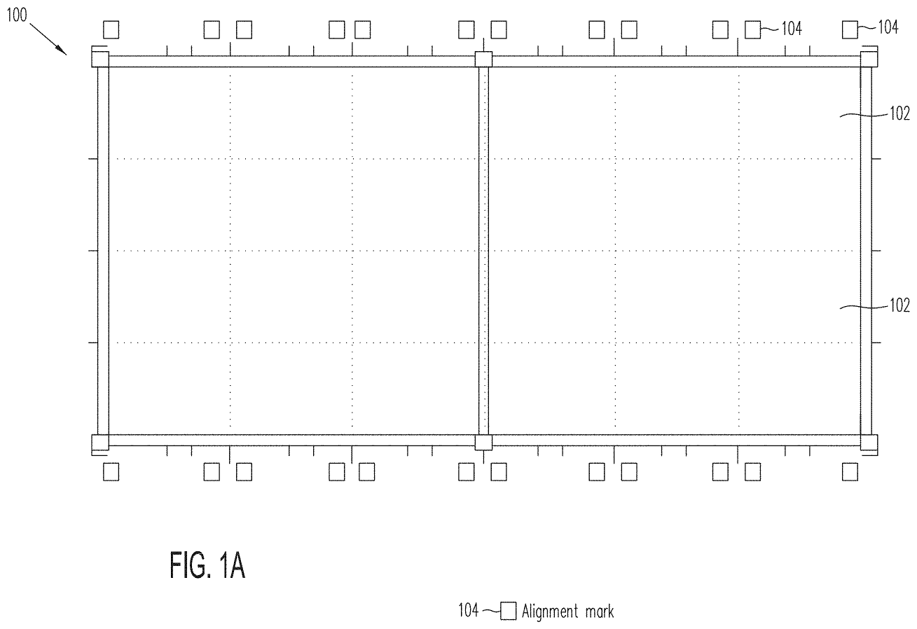

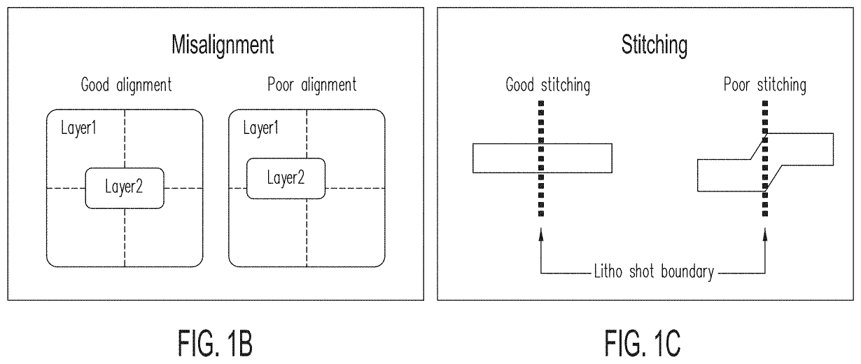

FIG. 1A is a schematic top view of a flat panel display or image sensor array 100 having corresponding alignment marks. All of the alignment marks 104 are located outside of the active area, so these only provide the alignment accuracy around the edge or corner of the active area. The active area comprises of a plurality of sub-arrays 102, which can coincide with a lithographic boundary. The locations of the alignment marks outside of the active area may not provide precise alignment accuracy in the active area that can lead to cluster defects.

FIG. 1B shows the alignment and misalignment of two layers, Layer1 and Layer2, that may be used in the manufacturing steps of the image sensor array. A proper alignment of the two layers will result in the features of the second layer being precisely located with respect to a predetermined location of the first layer. A poor alignment of the two layers will result in the features of the second layer being undesirably offset with respect to the predetermined location of the first layer.

FIG. 1C shows the lithographic boundary of a material layer, film, or mask used during the manufacturing method. If, for example, a given section of a material layer is properly aligned and properly stitched to a previous section of the material layer, a feature thereof will continue across a lithographic shot boundary without any discontinuities or undesirable artifacts. If the two sections are not properly aligned and therefore not properly stitched, shifting will cause some sort of undesirable artifact linking two portions of a feature across the lithographic shot boundary.

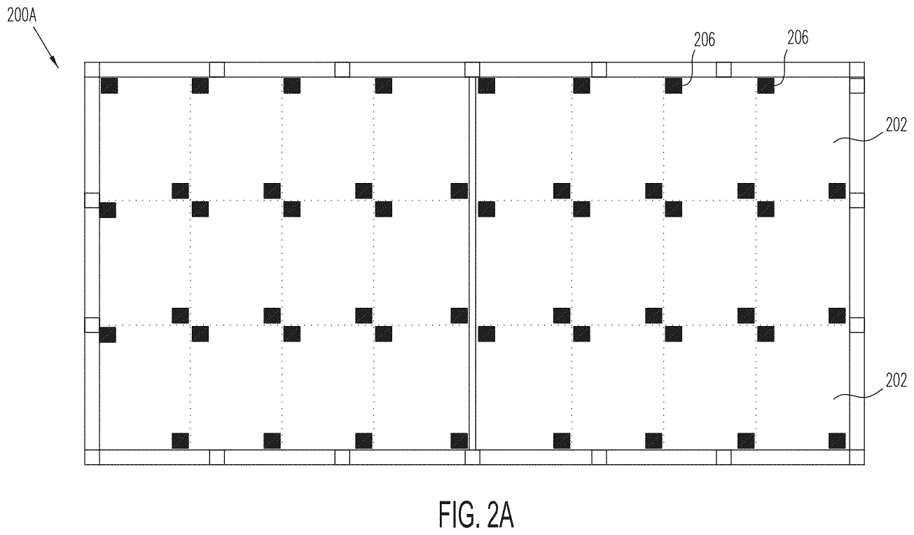

FIG. 2A is a schematic view of the sub-arrays 202 of the active area of the image sensor 200A according to the present invention, having the alignment marks 206 in the active area. The alignment marks are located around the lithographic shot boundaries in the active area, in addition to alignment marks in locations outside of the active area (the additional alignment marks are not shown in FIG. 2A). The alignment marks 206 in the active area can provide the accurate lithography shot-to-shot alignment in the active area and can be used for the accurate alignment required to minimize defects in the image array.

FIG. 2B is similar to FIG. 2A, but includes the additional alignment marks 204 that reside outside of the active area. The active area includes sub-arrays 202 including alignment marks 206 as previously described.

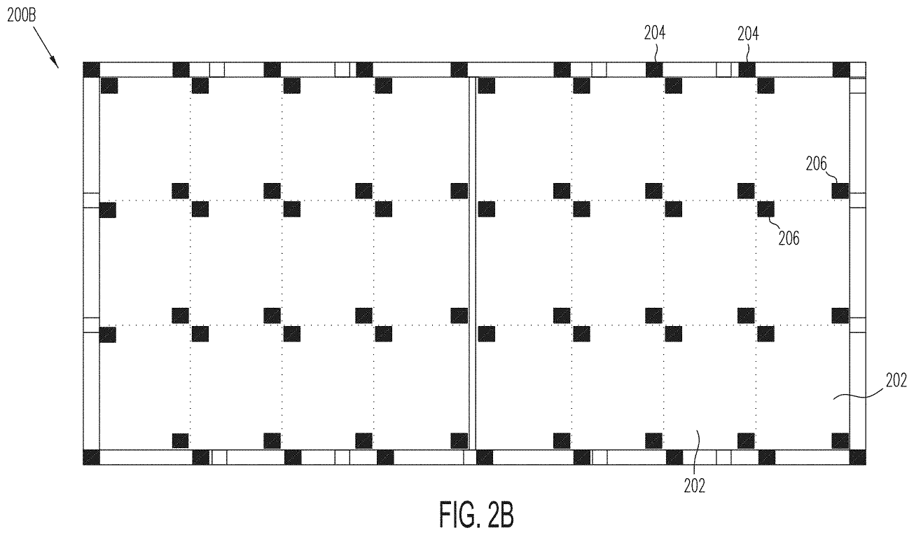

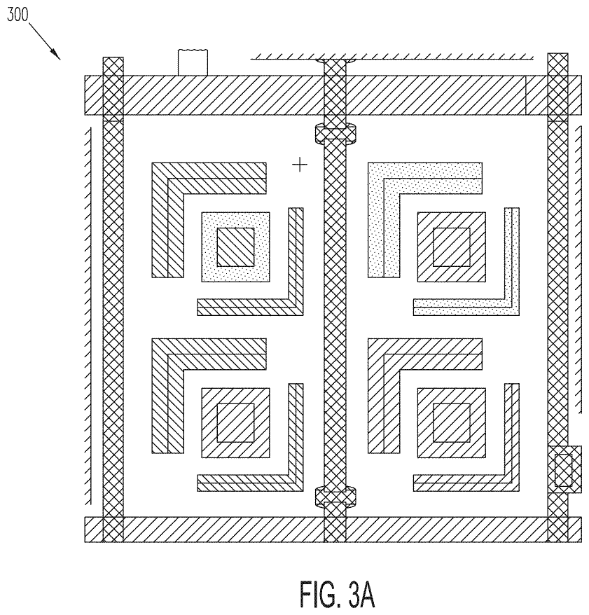

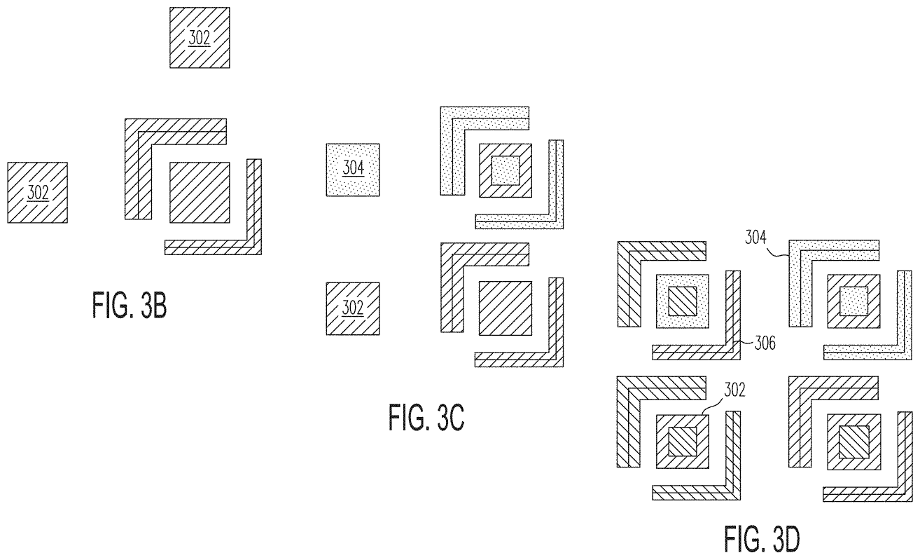

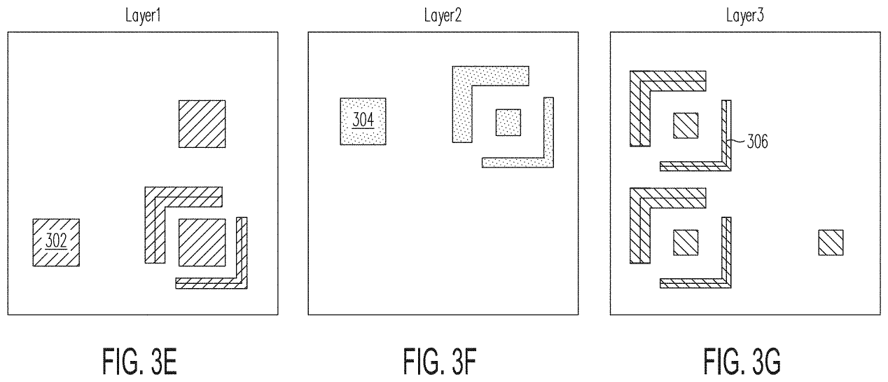

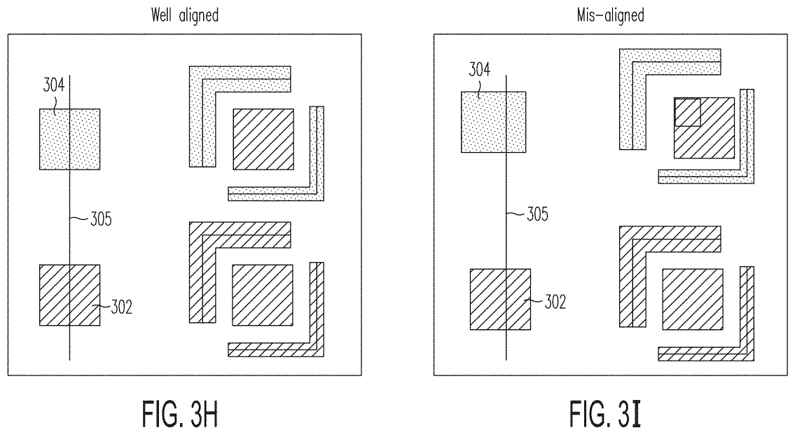

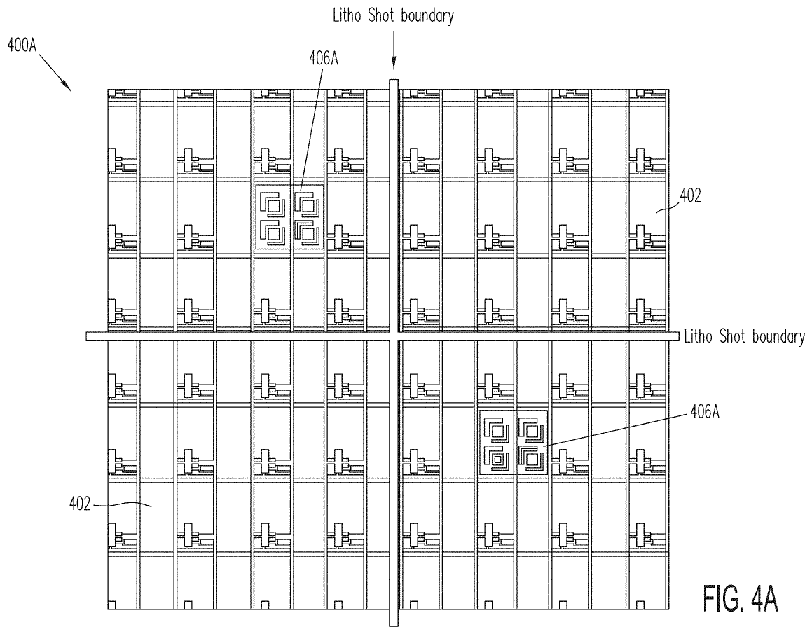

FIG. 3A is an example of the alignment marks replacing the pixel in the active area. The alignment mark 300 shown in FIG. 3A resides at a pixel location that would otherwise normally contain a pixel of a sensor array. The alignment mark structure, comprised of the stacked layers, is used as a means of measuring the misalignment. The pixel structure of the sensor array includes a first layer which is formed over a transparent substrate and acts as an alignment reference to the next layers and an alignment reference to the adjacent lithographic shot. Thereafter, the second layer patterns are formed over the first layer patterns looking at the first layer patterns. The next layers are formed and act in a same way. Alignment mark 300 is thus a composite of at least three or more layers, which is shown in further detail in successive drawing figures for a better understanding of each layer.

FIG. 3B shows a first layer 302 of alignment mark 300. The first layer could represent, for example, a gate layer or film. Layer 302 of alignment mark 300 shows a plurality of rectangular and square features in a specific layout that is convenient for registering subsequent layers. Other types of alignment mark feature shapes and spacings therebetween can be used. A second embodiment of the alignment marks according to the present is described below in further detail.

FIG. 3C shows a second layer 304 of alignment mark 300 properly aligned with the first layer 302 of the alignment mark 300. The second layer could represent, for example, a source/drain layer or film. Layer 304 of alignment mark 300 also shows a plurality of rectangular and square features in a specific layout with specific spacings that have been aligned to layer 302. Other types of alignment mark feature shapes and spacing therebetween can also be used for layer 304.

FIG. 3D shows a third layer 306 of alignment mark 300 properly aligned with the first layer 302 and the second layer 304 of the alignment mark 300. The third layer could represent, for example, a top metal layer or film.

FIG. 3E shows all of the first layer alignment mark features 302 on the same figure. FIG. 3F shows all of the second layer alignment mark features 304 on the same figure. FIG. 3G shows all of the third layer alignment mark features 306 on the same figure.

FIG. 3H shows a well-aligned alignment mark wherein alignment mark features 302 and 304 align to the same vertical axis 305. FIG. 3I show a mis-aligned alignment mark wherein alignment mark features 302 and 304 do not align to the same vertical axis 305.

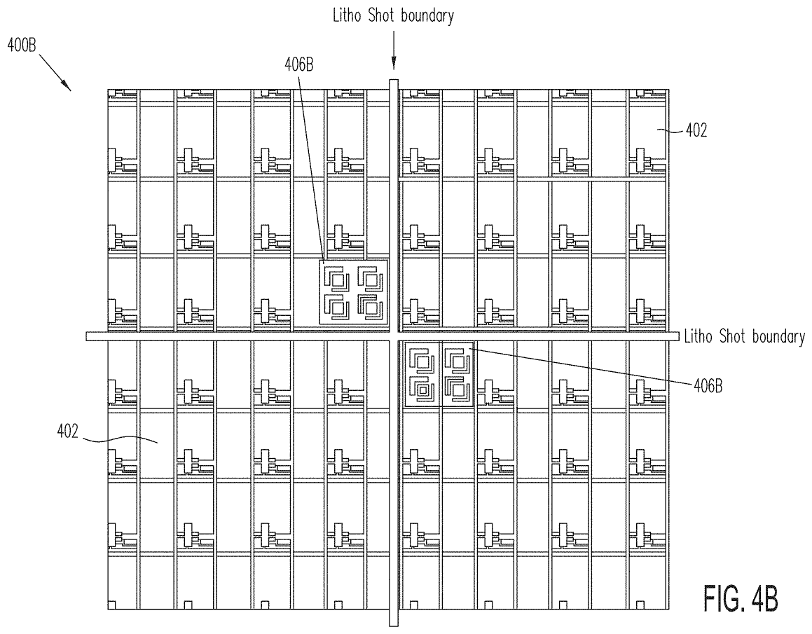

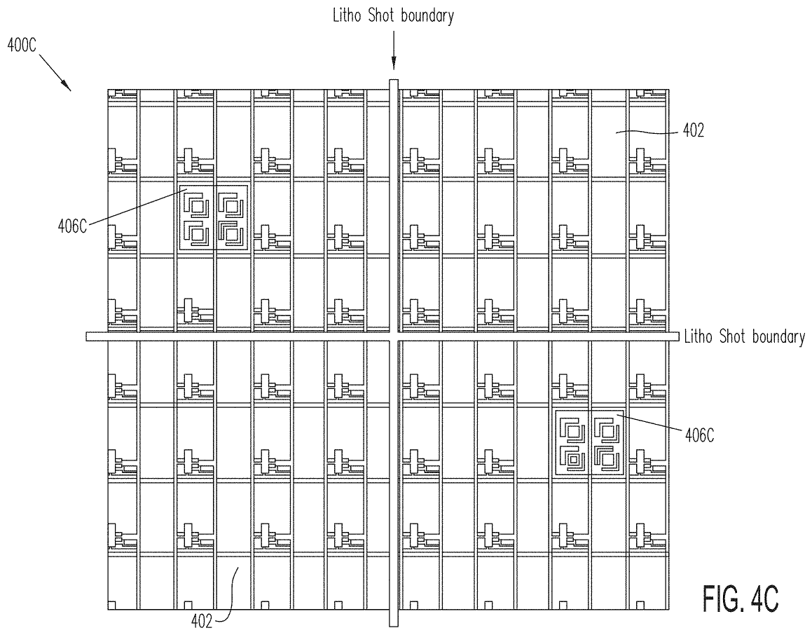

FIG. 4A is a schematic view of an image sensor portion 400A including alignment marks 406A located in the active area replacing the pixels in certain pixel locations and sub-arrays 402. The alignment marks 406A are located close to a crossing of the lithographic shot boundaries. For example, in the example of FIG. 4A, each alignment mark 406A is located one pixel away from a lithographic shot boundary in the x-direction, and one pixel away from a corresponding lithographic shot boundary in the y-direction.

FIG. 4B is a schematic view of an image sensor portion 400B including alignment marks 406B located in the active area replacing the pixels in certain pixel locations and sub-arrays 402. The alignment marks 406B are located close to a crossing of the lithographic shot boundaries. For example, in the example of FIG. 4B, each alignment mark 406B is located directly adjacent to a lithographic shot boundary in the x-direction, and directly adjacent to a corresponding lithographic shot boundary in the y-direction.

FIG. 4C is a schematic view of an image sensor portion 400C including alignment marks 406C located in the active area replacing the pixels in certain pixel locations and sub-arrays 402. The alignment marks 406C are located close to a crossing of the lithographic shot boundaries. For example, in the example of FIG. 4C, each alignment mark 406C is located two pixels away from a lithographic shot boundary in the x-direction, and one pixel away from a corresponding lithographic shot boundary in the y-direction.

It will be understood by those skilled in the art with respect to FIGS. 4A-4C that other pixel locations can be used for placing the alignment marks according to the present invention. For example, the alignment marks can be placed even three or more pixel locations away from the lithographic shot boundary. Multiple locations can be used if desired in each image sensor sub-array for even tighter alignment. The usefulness of multiple alignment marks within each sensor sub-array is of course mitigated by the loss of data that could be acquired by a corresponding active pixel at that location. The locations of the alignment marks can be adjusted as desired depending on particular process and manufacturing requirements.

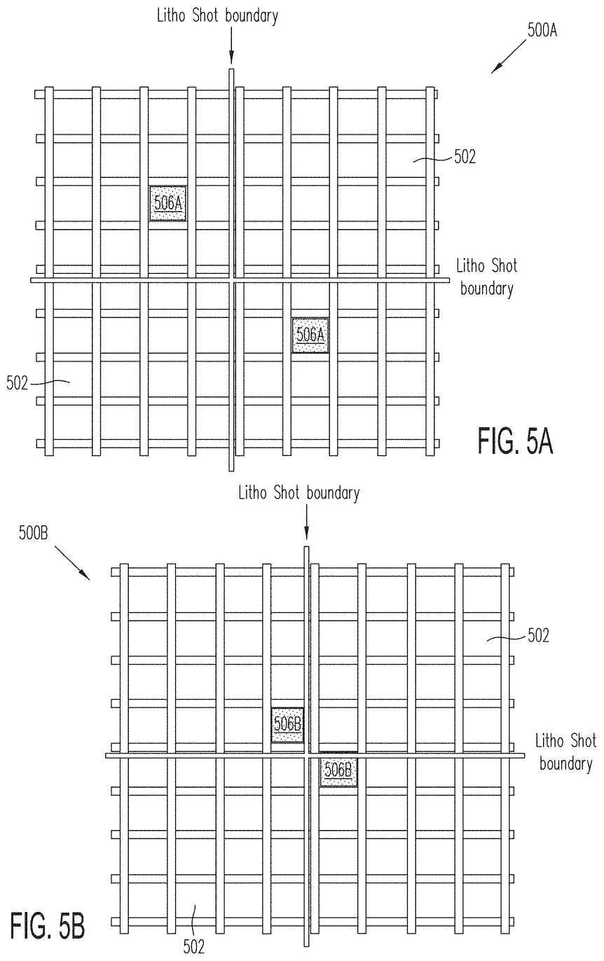

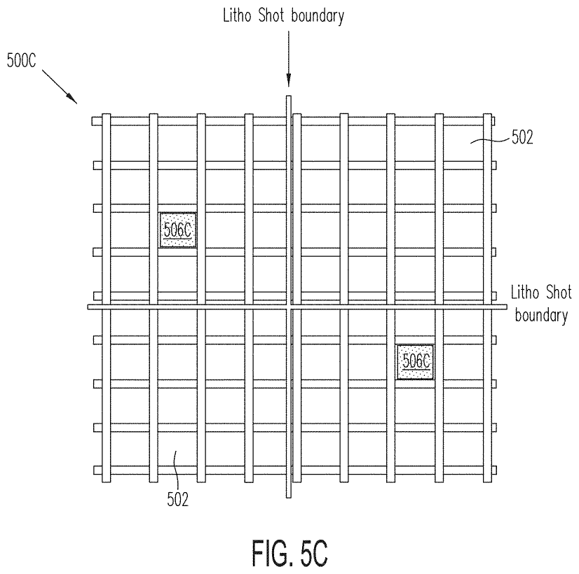

FIG. 5A is a simplified version of FIG. 4A showing an image sensor portion 500A, sub-arrays 502, and alignment marks 506A.

FIG. 5B is a simplified version of FIG. 4B showing an image sensor portion 500B, sub-arrays 502, and alignment marks 506B.

FIG. 5C is a simplified version of FIG. 4C showing an image sensor portion 500C, sub-arrays 502, and alignment marks 506C.

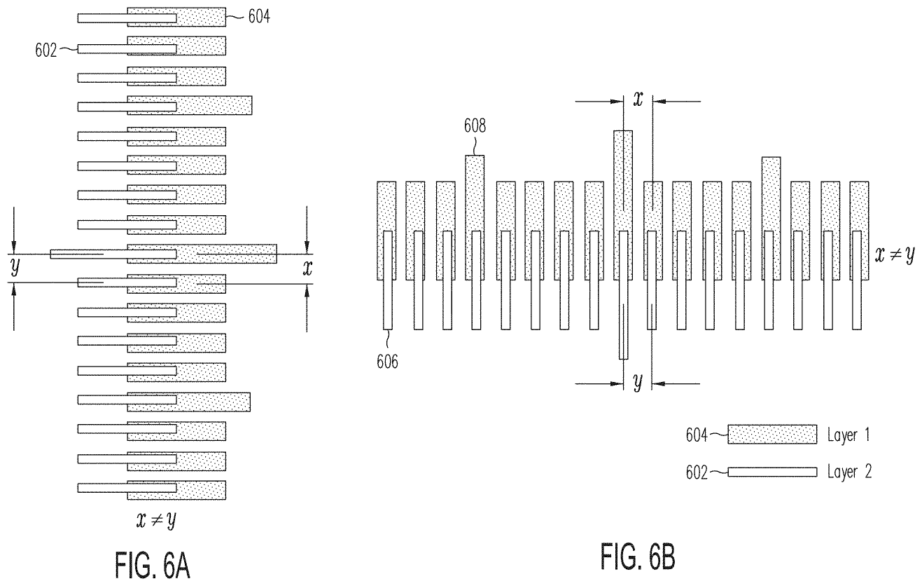

FIG. 6A shows an alignment mark comprising an overlapping plurality of rectangular features including a first layer 604 and a second layer 602 in a first orientation. FIG. 6B shows another portion of the alignment mark also including an overlapping plurality of rectangular features including a first layer 608 and a second layer 606 in a second orientation. The alignment mark in FIG. 6A is for checking the vertical misalignment in the sensor array and the alignment mark in FIG. 6B is for checking the horizontal misalignment in the sensor array. A complete alignment mark is placed in pairs including both portions as shown in FIGS. 6A and 6B. The bars designated 602 and 606 have a different spacing (y) from that of the bars designated 604 and 608 (x). The longest bars are reference points. If the alignment is perfect, the longest bar designated 604, 608 and the longest bar designated 602, 606 are arranged in a straight line. If there is some misalignment, bars other than the matching longest bar are arranged in a straight line. The degree of the misalignment is measured based on which bars are arranged in a straight line, which is readily discernible from an inspection of the alignment marks.

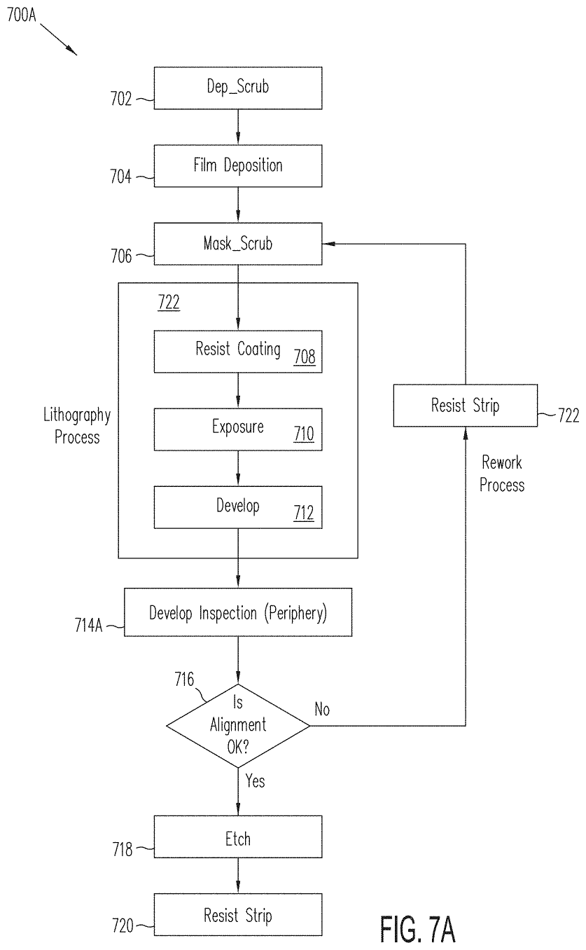

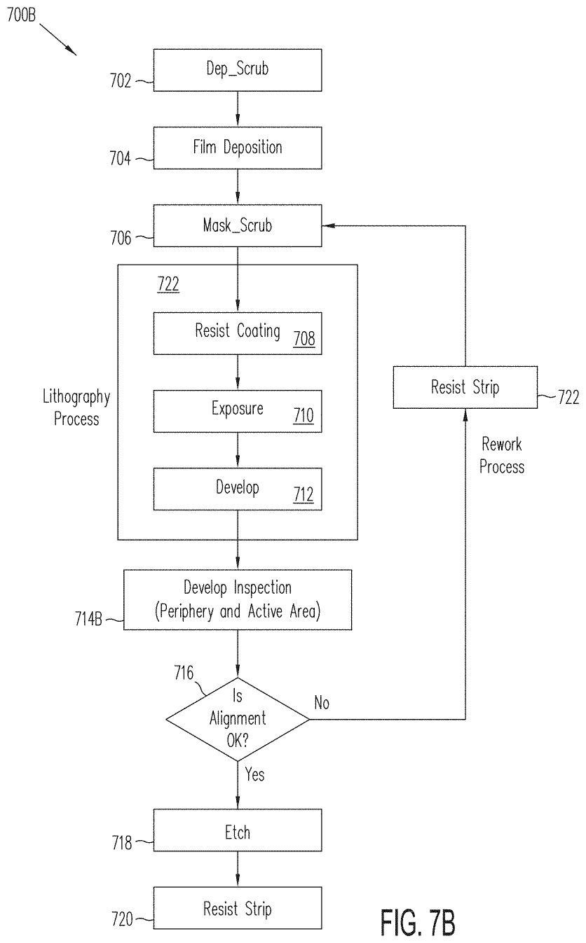

FIG. 7A shows a flow chart 700A of how the alignment marks shown in FIG. 1A can be used in a manufacturing process. At step 702, a Dep_Scrub scrubbing process is performed. The scrub process is a process for cleaning the plates using DI water with or without a detergent. Undesired particles and other contamination are removed by this step. Dep_Scrub is a cleaning process that is performed before film deposition. At step 704, a film is deposited, for example a metal or dielectric film. At step 706 a mask scrub is performed. According to the present invention the scrub (or plate cleaning) is a process step that is performed prior to a mask (lithography) process (also known as “Mask_Scrub”). At step 708 a resist coating is applied to the partially-formed sensor array. The resist coating is exposed at step 710. The resist coating is developed at step 712. Steps 708, 710, and 712 are related to the lithography process for adding a given layer onto to the partially-formed image sensor device. At step 714A, the developed photoresist layer is inspected, wherein the alignment marks are located around the periphery of the sensor array. If the alignment marks between the previous layer and the developed photoresist are acceptable at decision block 716, then the photoresist layer is etched 718 and subsequently stripped 720. The manufacturing process then continues with subsequent material layers. If the alignment marks between the previous layer and the developed photoresist are not acceptable at decision block 716, then the photoresist layer is stripped at step 722 and returned to step 706 of the manufacturing process for a rework of the partially-formed sensor array. Note that in FIG. 7A a perfect alignment of the two sets of alignment marks could still result in defects in the sensor array as has been previously described.

FIG. 7B corresponds to FIG. 7A, but uses the alignment marks shown in FIGS. 2A and 2B. Thus, a develop inspection step 714B is shown in which the alignment of alignment marks within the active area of the sensor array is inspected. If these alignment marks are successfully aligned then fewer defects can be expected within the sensor array. This also results in fewer reworks, higher quality image sensor devices, and an increase in productivity in the manufacturing process.

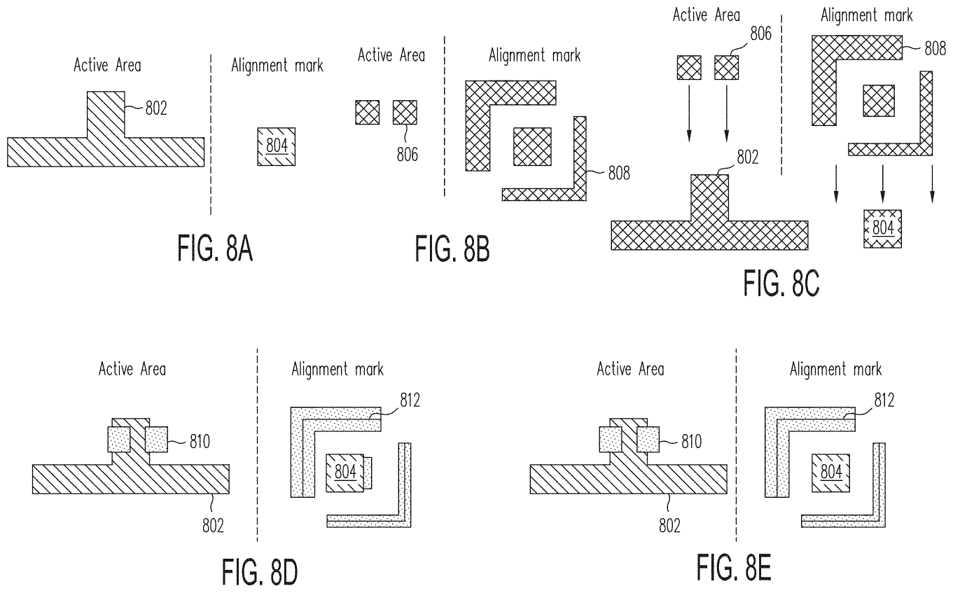

FIGS. 8A-8E show manufacturing process steps wherein the alignment marks are lined up properly, and manufacturing process steps wherein the alignment marks are misaligned, according to the present invention. For example, FIG. 8A shows a first layer patterned to include an active area pattern 802 and an alignment mark 804. FIG. 8B shows a portion of a mask that will be used for the second layer, corresponding to the features shows in FIG. 8A. The mask of FIG. 8B shows active area features 806 and alignment mark features 808. FIG. 8C shows the mask being exposed of the corresponding first layer. Active area mask features 806 are directly overhead corresponding active area features 802. Alignment mark mask features 808 are directly overhead corresponding alignment mark features 804. In FIG. 8D, a misalignment has occurred, wherein the active area features 810 in the second layer are not aligned to the underlying active area features 802 in the first layer. Similarly, alignment mark features 812 are clearly not aligned with the alignment mark features 804 from the first mask. In FIG. 8E, a perfect alignment has occurred, wherein the active area features 810 in the second layer are properly aligned to the underlying active area features 802 in the first layer. Similarly, alignment mark features 812 are clearly aligned with the alignment mark features 804 from the first mask.

It is an advantage that only minor changes of a photomask set is required to produce the alignment marks according to the present invention. No extensive re-layout of the photomask set is required. Therefore, the steps for making the alignment mark are fully compatible with the conventional flat panel array/medical image array manufacturing process.

It is another advantage of the present invention that the alignment in the active area can accurately discriminate a higher degree of alignment between the lithography shots in the active area. Therefore, this aspect of the invention can result in a better alignment in the active area.

Although the invention has been described and illustrated with a certain degree of particularity, it is understood that the present disclosure has been made only by way of example, and that numerous changes in the combination and arrangement of parts can be resorted to by those skilled in the art without departing from the spirit and scope of the invention, as hereinafter claimed.

What is claimed is:

1. A method of manufacturing an image sensor device comprising:
providing a glass substrate;
forming at least one layer of the image sensor device, the at least one layer including a first plurality of alignment marks within an active area of the image sensor device, the alignment marks each comprising a plurality of square and rectangular features;
coating the at least one layer with a film;
coating the film with a photoresist layer, the photoresist layer including a second plurality of alignment marks within an active area of the image sensor device, the alignment marks each comprising a plurality of square and rectangular features; and
inspecting the alignment between the first plurality of alignment marks and the second plurality of alignment marks.

2. The method of claim 1 further comprising stripping the photoresist layer if the alignment between the first plurality of alignment marks and the second plurality of alignment marks is unacceptable.

3. The method of claim 1 further comprising etching the film using the photoresist layer if the alignment between the first plurality of alignment marks and the second plurality of alignment marks is acceptable.

4. The method of claim 1, wherein at least one of the first or second plurality of alignment marks is placed in a pixel location of the active area.

5. The method of claim 1, wherein at least one of the plurality of alignment marks is placed proximate to a lithographic boundary of the active area.

6. A method of manufacturing an image sensor device comprising:
providing a glass substrate;
forming at least one layer of the image sensor device, the at least one layer including a first plurality of alignment marks within an active area of the image sensor device, the alignment marks each comprising a plurality of overlapping rectangular features;
coating the at least one layer with a film;
coating the film with a photoresist layer, the photoresist layer including a second plurality of alignment marks within an active area of the image sensor device, the alignment marks each comprising a plurality of overlapping rectangular features; and
inspecting the alignment between the first plurality of alignment marks and the second plurality of alignment marks.

7. The method of claim 6 further comprising stripping the photoresist layer if the alignment between the first plurality of alignment marks and the second plurality of alignment marks is unacceptable.

8. The method of claim 6 further comprising etching the film using the photoresist layer if the alignment between the first plurality of alignment marks and the second plurality of alignment marks is acceptable.

9. The method of claim 6, wherein at least one of the first or second plurality of alignment marks is placed in a pixel location of the active area.

10. The method of claim 6, wherein at least one of the plurality of alignment marks is placed proximate to a lithographic boundary of the active area.
